(19) United States
(12) Patent Application Publication
(10) Pub. No.: US 2026/0143682 A1
(43) Pub. Date: May 21, 2026

(54) SEMICONDUCTOR DEVICE

(71) Applicant: Samsung Electronics Co., Ltd., Suwon-si, (KR)

(72) Inventors: HYOKYOUNG KIM, Suwon-si, (KR); JU-EUN KIM, Suwon-si, (KR); CHUNHYUNG CHUNG, Suwon-si, (KR); DONGSIK KONG, Suwon-si, (KR)

(21) Appl. No.: 19/392,913

(22) Filed: Nov. 18, 2025

(30) Foreign Application Priority Data
Nov. 18, 2024 (KR) 10-2024-0164596

(51) Int. Cl. H10B 12/00; H10D 64/27

(52) U.S. Cl. CPC H10B 12/34; H10B 12/05; H10B 12/482; H10B 12/488; H10D 64/513; H10D 64/516; H10D 64/518

(57) ABSTRACT

A semiconductor device includes a substrate including a gate trench region, a first impurity region and a second impurity region spaced apart from each other by the gate trench region, a gate insulating pattern covering a bottom surface and a side surface of the gate trench region, and a gate electrode disposed at a portion of the gate trench region. The gate insulating pattern may cover the bottom surface and the side surface of the gate trench region. The gate insulating pattern may have different thicknesses depending on a location of the gate insulating pattern on the side surface of the gate trench region, and the thickness of the gate insulating pattern on the bottom surface of the gate trench region may be the same as one of the thicknesses of the gate insulating pattern on the side surface of the gate trench region.

### CROSS-REFERENCE TO RELATED APPLICATION(S)

This application claims priority under 35 USC § 119 to Korean Patent Application No. 10-2024-0164596, filed on Nov. 18, 2024, in the Korean Intellectual Property Office, the entirety of which is herein incorporated by reference.

### BACKGROUND

With the advancement of the electronics industry, techniques for forming interconnections and electrodes with various structures are introduced to manufacture semiconductor devices that can have reduced sizes and improved performance.

### SUMMARY

This disclosure describes a semiconductor device, including a semiconductor device having a buried wordline structure, and a method of forming manufacturing a semiconductor device by which reliability can be improved.

In some implementations, a semiconductor device includes a substrate including a gate trench region, a first impurity region and a second impurity region spaced apart from each other by the gate trench region, a gate insulating pattern covering a bottom surface and a side surface of the gate trench region, and a gate electrode filling a portion of the gate trench region. The gate insulating pattern may cover the bottom surface and the side surface of the gate trench region. The gate insulating pattern may have different thicknesses depending on a location of the gate insulating pattern on the side surface of the gate trench region, and a thickness of the gate insulating pattern on the bottom surface of the gate trench region may be the same as a thickness of a portion of the gate insulating pattern on the side surface of the gate trench region.

In some implementations, a semiconductor device includes a substrate including an active region including a first impurity region and a second impurity region, a wordline structure extending in one direction within a gate trench region in the substrate, a bitline structure extending in another direction, intersecting the one direction, on the substrate and connected to the first impurity region on one side of the gate structure, and a data storage pattern disposed on the bitline structure and electrically connected to the second impurity region on another side of the wordline structure. The wordline structure may include a gate insulating pattern covering a bottom surface and a side surface of the gate trench region and a gate electrode filling a portion of the gate trench region. The gate insulating pattern may cover the bottom surface and the side surface of the gate trench region. The gate insulating pattern may have different thicknesses depending on a location of the gate insulating pattern on the side surface of the gate trench region, and a thickness of the gate insulating pattern on the bottom surface of the gate trench region may be the same as a thickness of a portion of the gate insulating pattern on the side surface of the gate trench region.

In some implementations, a method of manufacturing a semiconductor device includes forming a gate trench region on a substrate, forming a first gate insulating pattern on a bottom surface and a side surface of the gate trench region, the first gate insulating pattern having different thicknesses depending on a location of the first gate insulating pattern on the side surface of the gate trench region, forming a first gate electrode in a portion of the gate trench region, forming a second gate insulating pattern on the side surface of the gate trench region, and forming a second gate electrode on the first gate electrode. The forming of the second gate insulating pattern may include forming the second gate insulating pattern such that a sum of thicknesses of the first and second gate insulating patterns on the side surface of the gate trench region is the same as a thickness of the first gate insulating pattern on the bottom surface of the gate trench region.

### BRIEF DESCRIPTION OF DRAWINGS

FIG. 1 is a plan view of a semiconductor memory device according to some implementations

FIG. 2A is a cross-sectional view corresponding to line A-A′ of FIG. 1. FIG. 2B is a cross-sectional view corresponding to line B-B′ of FIG. 1. FIG. 2C is a cross-sectional view corresponding to line C-C′ of FIG. 1.

FIG. 3A is an enlarged view of portion P1 of FIG. 2B. FIG. 3B is an enlarged view of portion P2 of FIG. 2C.

FIGS. 4A and 4B, 5A and 5B, 6A and 6B, 7A and 7B, 8A and 8B, and 9A and 9B are cross-sectional views sequentially illustrating a method of manufacturing a buried wordline structure according to some implementations.

### DETAILED DESCRIPTION

Hereinafter, implementations of the present disclosure will be described with reference to the accompanying drawings.

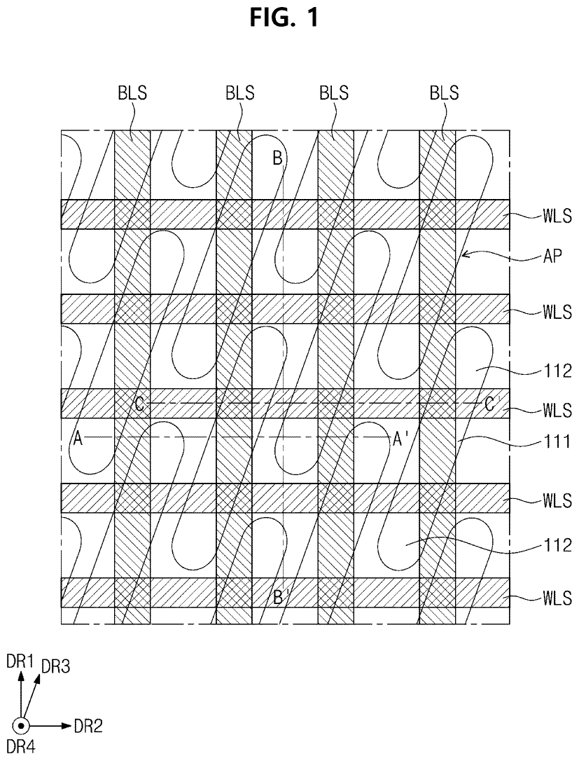

FIG. 1 is a plan view of a semiconductor memory device according to some implementations.

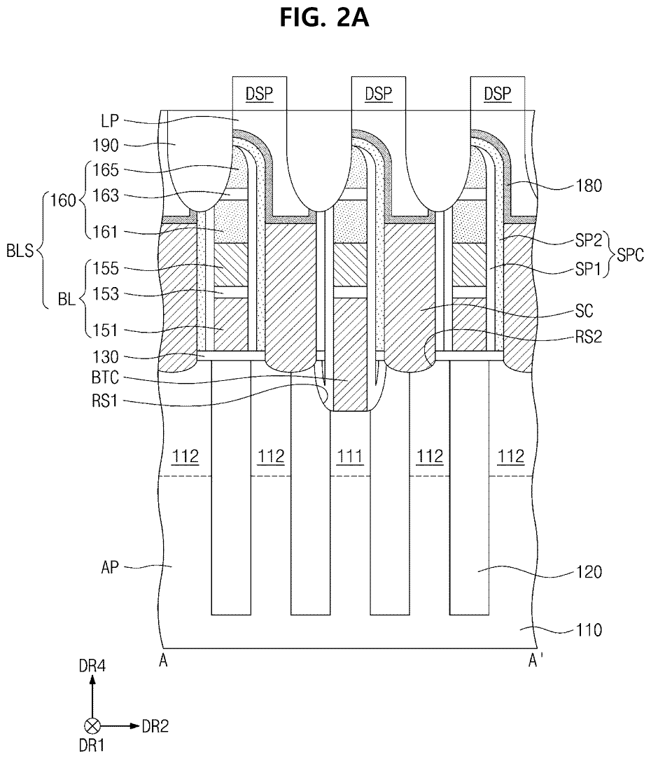

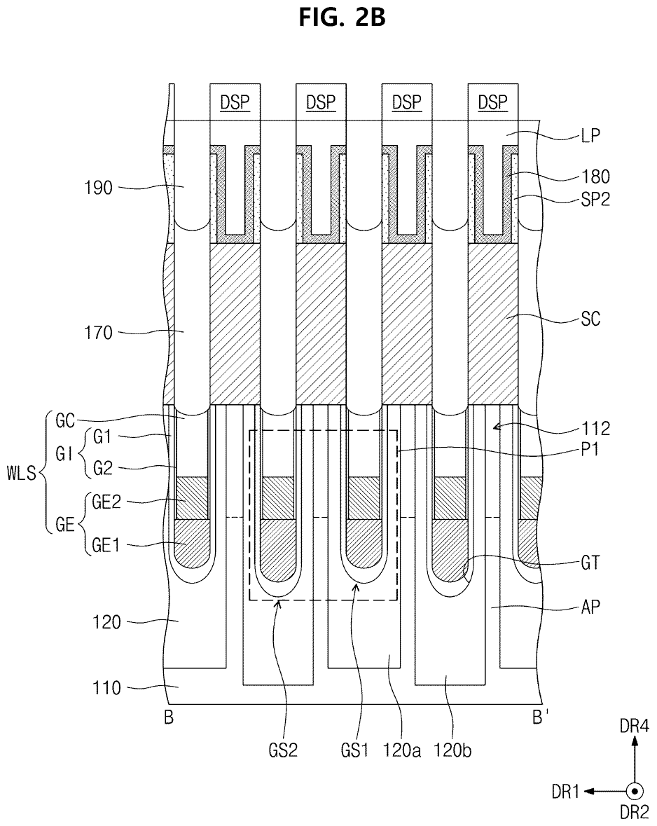

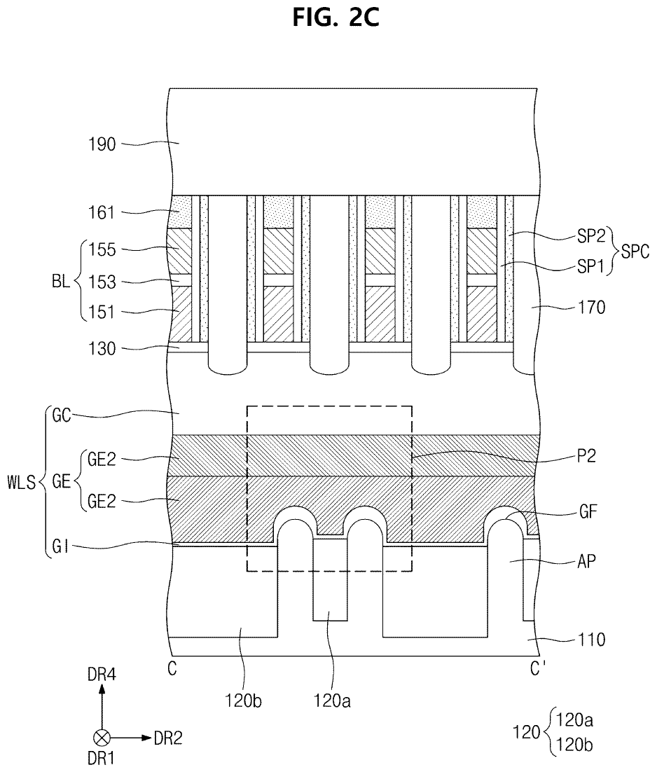

FIGS. 2A to 2C are cross-sectional views corresponding to lines A-A′, B-B′, and C-C′ of FIG. 1, respectively.

Referring to FIG. 1 and FIGS. 2A to 2C, a semiconductor device according to an some implementations may include a substrate 110, a wordline structure WLS, a bitline structure BLS, a bitline contact BTC, a storage node contact SC, a landing pad LP, and a data storage pattern DSP.

The substrate 110 may include, for example, a group IV semiconductor, a group III-V compound semiconductor, or a group II-VI compound semiconductor. For example, the group IV semiconductor may include silicon, germanium, or silicon-germanium. The substrate 110 may be a silicon substrate, a silicon-on-insulator (SOI) substrate, a germanium substrate, a germanium-on-insulator (GOI) substrate, a silicon-germanium substrate, or a substrate including an epitaxial layer.

The substrate 110 may include active patterns AP, device isolation patterns 120, and first impurity regions 111 and second impurity regions 112.

The device isolation patterns 120 may be disposed within the substrate 110 and may define the active patterns AP. The active patterns AP may be spaced apart from each other in a first direction DR1 and a second direction DR2, which intersect each other (for example, orthogonally). The first directions DR1 and second directions DR2 may be parallel to a lower surface of the substrate 110.

The device isolation patterns 120 may surround the active patterns AP, spacing the active patterns AP apart from each other. The device isolation patterns 120 may include a silicon oxide, a silicon nitride, a silicon oxynitride, or combinations thereof, and may include a single layer or a plurality of layers.

In some implementations, the device isolation patterns 120 may include regions having different bottom levels. The device isolation patterns 120 may include first regions 120a and second regions 120b lower than the first regions 120a.

Each of the active patterns AP may have a separate island shape and may be in the form of a bar elongated in a third direction DR3. The third direction DR3 may be parallel to the lower surface of the substrate 110 and may intersect (for example, be orthogonal to) the first directions DR1 and second directions DR2. Alternatively, the third direction DR3 may intersect the first direction DR1 at an angle other than 90 degrees, for example, an acute angle. When viewed in plan view, the active patterns AP may be portions of the substrate 110 surrounded by the device isolation patterns 120. The active patterns AP may have a shape protruding in a fourth direction DR4, perpendicular to the lower surface of the substrate 110. The device isolation patterns 120 may include an insulating material. For example, the device isolation pattern 120 may include at least one of a silicon oxide, a silicon nitride, or a combination thereof.

The first impurity regions 111 and the second impurity regions 112 may be provided within the active patterns AP. The second impurity regions 112 may be provided within both edge regions of each of the active patterns AP. In some cases, the first impurity regions 111 may be positioned between the second impurity regions 112 within each active pattern AP.

The first impurity regions 111 and second impurity regions 112 may be provided as source/drain regions of a transistor. In some implementations, with respect to a single active pattern (AP), two wordline structures WLS may cross the active pattern AP, and a drain region may be formed between the two wordline structures WLS. Source regions may be formed in regions opposite to a drain region relative to the two wordline structures WLS. In some examples, the first impurity region 111 may correspond to the drain region, and the second impurity region 112 may correspond to the source region. The source region and the drain region are formed by the first impurity regions 111 and second impurity regions 112 by doping or ion implantation of substantially the same type of impurities. The first impurity regions 111 and the second impurity regions 112 (and thus the drain region and the source region) may be interchangeable, depending on the circuit configuration of the formed transistor. The first impurity regions 111 and the second impurity regions 112 may include impurities having a conductivity opposite to that of the substrate 110. In some implementations, the active patterns AP may include p-type impurities, and the first impurity region 111 and second impurity regions 112 may have n-type impurities.

The wordline structure WLS may be provided in a plurality of forms. The wordline structures WLS may extend in the second direction DR2 and may be spaced apart from each other in the first direction DR1.

Referring to FIG. 2B, each of the wordline structures WLS may include a buried gate structure disposed within a gate trench region GT.

The wordline structures WLS extend in the second direction DR2 and may be spaced apart from each other in the first direction DR1. In some implementations, the wordline structures WLS may include first gate structures GS1 and second gate structures GS2, alternately disposed in the first direction DR1. The second gate structure GS2 may have a structure that is the same as or similar to that of the first gate structure GS1.

The wordline structures WLS may cross the active pattern AP. For example, first gate structures GS1 and second gate structures GS2 may intersect in a single active pattern AP. The first gate structures GS1 and second gate structures GS2, respectively including the wordline structure WLS and the first impurity regions 111 and second impurity regions 112, may include a buried channel array transistor BCAT.

In plan view, the first gate structures GS1 may be arranged in a zigzag pattern with the second gate structures GS2. For example, opposite ends of the first gate structures GS1, spaced apart from each other in the second direction DR2, may be arranged in a zigzag pattern with opposite ends of each second gate structure GS2 spaced apart from each other in the second direction DR2.

The wordline structures WLS may be buried in the substrate 110. For example, the first gate structures GS1 and the second gate structures GS2 may be disposed inside gate trench regions GT and fin regions GF formed in the substrate 110, respectively. The gate trench regions GT may refer to extended regions recessed into the device isolation patterns 120. The gate trench regions GT may be provided in the device isolation patterns 120 between the first impurity regions 111 and the second impurity regions 112. For example, the first impurity regions 111 and the second impurity regions 112 may be spaced apart from each other by the gate trench regions. The fin regions GF may refer to regions recessed into the device isolation patterns 120, with a top surface of the active pattern AP exposed in a fin shape.

When viewed in plan view, each of the gate trench regions GT may have a line shape extending in one direction. The gate trench regions GT may have a line shape crossing the active patterns AP and the device isolation patterns 120. A lower portion of the gate trench region GT may have a curvature.

A top surface of the active pattern AP may have an upwardly convex shape, and may be provided at a higher level than the top surface of the device isolation pattern 120. Accordingly, the fin regions GF may be provided deeper than the gate trench regions GT. The gate trench regions GT and the fin regions GF may have bottom surfaces disposed at different levels, and the bottom surface of the fin regions GF may be provided at a lower level than the bottom surface of the gate trench regions GT.

The fin regions GF may be continuously connected from the gate trench regions GT. A height difference between the gate trench regions GT and the fin regions GF is caused by recession of the device isolation patterns 120. Due at least in part to a step between the gate trench regions GT and the fin regions GF, the fin regions GF may be formed in the active patterns AP.

A side surface of the fin region GF may correspond to a side surface of the active pattern AP and may be exposed by the recessed device isolation patterns 120. A portion of the channel may be formed in the fin regions GF. The fin region GF may be referred to as a saddle fin. A channel width may be increased through the fin regions GF, and electrical characteristics of the transistor may be improved.

Each of the wordline structures WLS may include a gate electrode GE, a gate insulating pattern GI, and a gate capping pattern GC.

The gate insulating pattern GI may cover a surface of the gate trench region GT and a surface of the fin region GF. The gate electrode GE may partially fill the gate trench region GT and the fin region GF on the gate insulating pattern GI.

The gate electrode GE may cross the active patterns AP and the device isolation patterns 120 in the second direction DR2. The gate insulating pattern GI may be interposed between the gate electrode GE and the active patterns AP and between the gate electrode GE and the device isolation patterns 120.

The gate capping pattern GC may cover the gate electrode GE on the gate electrode GE.

A buffer pattern 130 may be disposed on the substrate. The buffer pattern 130 may cover the active patterns AP, the device isolation patterns 120, and the wordline structures WLS. In some implementations, the buffer pattern 130 may include at least one of a silicon oxide, a silicon nitride, a silicon oxynitride, or combinations thereof.

The bitline structures BLS may extend in the first direction DR1 and may be spaced apart from each other in the second direction DR2. The bitline structures BLS may have a bar shape extending in the first direction DR1. Each of the bitline structures BLS may include a bitline BL and a bitline capping pattern 160 on the bitline BL.

The bitline BL may include first conductive layers 151, second conductive layers, 153, and third conductive layers 155 sequentially stacked on the buffer pattern 130. The first conductive layers 151 may include polysilicon. The second conductive layers 153 may include a metal-semiconductor compound. In some implementations, the metal-semiconductor compound may be a layer obtained by siliciding a portion of the first conductive layer 151. For example, the metal-semiconductor compound may include cobalt silicide (CoSi), titanium silicide (TiSi), nickel silicide (NiSi), tungsten silicide (WSi), or other metal silicides, or may include a nitride such as titanium silicon nitride (TiSiN). The second conductive layer 153 may include a conductive metal nitride. For example, the second conductive layer 153 may include at least one of a tungsten oxide, a rubidium oxide, a molybdenum oxide, or a titanium oxide, or combinations thereof. The third conductive layer 155 may include a metal material such as titanium (Ti), tantalum (Ta), tungsten (W), and aluminum (Al).

The bitline capping pattern 160 may include first capping patterns 161, second capping patterns 163, and third capping patterns 165 disposed on the bitline BL. A side surface of the first capping pattern 161 may be coplanar with the first conductive layer 151, the second conductive layer 153, and the third conductive layer 155. Each of the first insulating patterns 161, the second insulating patterns 163, and the third insulating patterns 165 may include a silicon oxide, a silicon nitride, a silicon oxynitride, or any combinations thereof. In some implementations, each of the first insulating patterns 161, the second insulating patterns 163, and the third insulating patterns 165 may include a silicon nitride.

A bitline contact BTC may be provided on each of the active patterns AP, and may be provided in a plurality of forms. The bitline contacts BTC may be connected to the first impurity regions 111 in the active patterns AP. The bitline contacts BTC may be spaced apart from each other in the first directions DR1 and second directions DR2. The bitline contacts BTC may each be interposed between the active patterns AP and the bitlines BL. The bitline contacts BTC may electrically connect a corresponding bitline BL, among the bitlines BL, and a corresponding first impurity region 111.

The bitline contacts BTC may be disposed in the first recess regions RS1, respectively. The first recess regions RS1 may be provided in an upper portion of the active patterns AP and in an upper portion of the device isolation patterns 120 adjacent to the upper portion of the active patterns AP. The first recess regions RS1 may be spaced apart from each other in the first directions DR1 and second directions DR2.

The bitline capping pattern 160 may be provided on a top surface of the bitline BL. The bitline capping pattern 160 may be provided in a plurality of forms. The bitline capping patterns 160 may each extend in the first direction DR1 along the corresponding bitline BL, and may be spaced apart from each other in the second direction DR2. The bitline capping patterns 160 may vertically overlap the bitline BL. The bitline capping patterns 160 may include a first capping pattern 161, a second capping pattern 162, and a third capping pattern 163, sequentially stacked on the top surface of the corresponding bitline BL. The bitline capping pattern 160 may include a silicon nitride.

A spacer structure SPC may be provided on a side surface of the bitline BL and a side surface of the bitline capping pattern 160. The spacer structure SPC may cover the side surface of the bitline BL and the side surface of the bitline capping pattern 160. The spacer structure SPC may be provided in a plurality of forms.

For example, the spacer structure SPC may include a first spacer SP1 and a second spacer SP2. The second spacer SP2 may be provided on the side surface of the bitline BL, and the first spacer SP1 may be interposed between the side surface of the bitline BL and the second spacer SP2. According to some implementations, the second spacer SP2 may cover a top surface of the bitline capping pattern 160.

The spacer structure SPC may be in contact with the side surface of the bitline capping pattern 160. For example, the first spacer SP1 may be in contact with the side surface of the bitline capping pattern 160. In some implementations, the first spacer SP1 may include a silicon oxide and the second spacer SP2 may include a silicon nitride. For example, the first spacer SP1 may include an empty space (for example, an air gap) including an air layer.

The first spacer SP1 and the second spacer SP2 may each fill a portion of the first recess regions RS1. The first spacer SP1 may conformally cover an inner surface of the first recess region RS1 and at least a portion of the side surface of the bitline contact BTC (for example, at least a portion of the side surface of the bitline contact BTC in the first recess region RS1). The second spacer SP2 may fill the remaining portion of the first recess region RS1. For example, the first spacer SP1 may include a silicon oxide, and the second spacer SP2 may include a silicon nitride.

A storage node contact SC may be provided between adjacent bitlines BL. The storage node contact SC may be provided in a plurality of forms, and the storage node contacts SC may be spaced apart from each other in the first directions DR1 and second directions DR2.

A lower end of the storage node contact SC may be disposed at a lower level than the top surface of the substrate 110, and a top surface of the storage node contact SC may be disposed at a lower level than an upper end of the bitline structure BLS. The storage node contact SC may extend inwardly of the substrate 110 to be in contact with the second impurity region 112 of the active pattern AP, and may be electrically connected to the second impurity region 112. The storage node contact SC may be formed of a conductive material. Suitable examples of the conductive material include at least one of polysilicon (polySi), titanium (Ti), titanium nitride (TiN), tantalum (Ta), tantalum nitride (TaN), tungsten (W), tungsten nitride (WN), or aluminum (Al). In some implementations, the storage node contact SC may include doped polysilicon, and may include N-type impurities such as phosphorus (P), arsenic (As), or antimony (Sb).

The storage node contacts SC may be spaced apart from each other in the first direction DR1 by fence patterns 170 on the wordline structures WLS.

The fence patterns 170 may be disposed between the bitline structures BLS, and may overlap the wordline structure WLS in the vertical direction. The fence patterns 170 may be alternately arranged with the storage node contacts SC in the first direction DR1. The fence patterns 170 may spatially separate the storage node contacts SC from each other, and may electrically insulate the storage node contacts SC from each other. A lower surface of the fence pattern 170 may be in contact with the gate capping pattern GC of the wordline structure WLS. In some implementations, the lower surface of the fence pattern 170 may have a downward convex surface toward the gate capping pattern GC, and a top surface of the gate capping pattern GC may have an upward concave surface. The lower surface of the fence pattern 170 may be disposed at a lower level than the top surface of the substrate 110. The fence pattern 170 may include an insulating material. A suitable example of the insulating material includes a silicon nitride.

The storage node contact SC may fill a second recess region RS2 provided on the second impurity region 112 in the active pattern AP. The storage node contact SC may be electrically connected to the second impurity region 112. The storage node contact SC may include at least one of doped or undoped polysilicon, a metal material, or a combination thereof.

A barrier pattern 180 may conformally cover the spacer structure SPC and the storage node contact SC. The barrier pattern 180 may include a metal nitride. Suitable examples of the metal nitride include titanium nitride or tantalum nitride. A second ohmic pattern, not illustrated, may be further interposed between the barrier pattern 180 and the storage node contact SC. The second ohmic pattern may include a metal silicide.

A landing pad LP may be provided on the storage node contact SC. The landing pad LP may be provided in a plurality of forms, and the landing pads LP may be spaced apart from each other in the first directions DR1 and second directions DR2. The landing pad LP may be electrically connected to a corresponding storage node contact SC. The landing pad LP may cover a top surface of the bitline capping pattern 160.

The landing pad LP may include a lower landing pad and an upper landing pad. The lower landing pad may be a lower region of the landing pad LP, and may vertically overlap the storage node contact SC. The upper landing pad may be an upper region of the landing pad LP, and may be shifted from the lower landing pad in the second direction DR2. The landing pad LP may include a metal material. Suitable examples of the metal material include tungsten, titanium, tantalum, or the like.

A filling pattern 190 may surround the landing pad LP. The filling pattern 190 may be interposed between the landing pads LP adjacent to each other. When viewed in plan view, the filling pattern 190 may have a mesh shape having holes through which the landing pads LP penetrate. For example, the filling pattern 190 may include at least one of a silicon nitride, a silicon oxide, a silicon oxynitride, or combinations thereof. In some implementations, the filling pattern 190 may include an empty space (for example, an air gap) including an air layer.

A data storage pattern DSP may be provided on the landing pad LP. The data storage patterns DSP may be provided in a plurality of forms, and the data storage patterns DSP may be spaced apart from each other in the first directions DR1 and second directions DR2. The data storage pattern DSP may be connected to a second impurity region 112 through a landing pad LP and a storage node contact SC.

For example, the data storage pattern DSP may be a capacitor including a lower electrode, a dielectric layer, and an upper electrode. The semiconductor memory device according to some implementations may be a dynamic random access memory (DRAM). For example, the data storage pattern DSP may include a magnetic tunnel junction pattern, and the semiconductor memory device according to some implementations may be a magnetic random access memory (MRAM). For example, the data storage pattern DSP may include a phase change material or a variable resistance material, and the semiconductor memory device according to some implementations may be a phase-change random access memory (PRAM) or a resistive random access memory (ReRAM). However, these are implementations, and the implementations are not limited thereto. The data storage pattern DSP may include various structures and/or materials, capable of storing data.

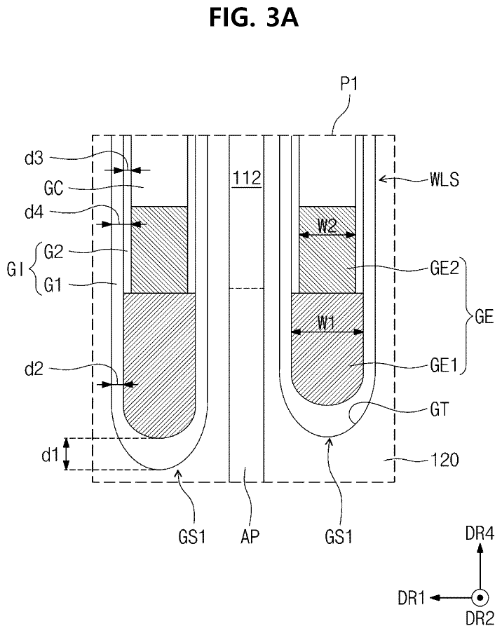

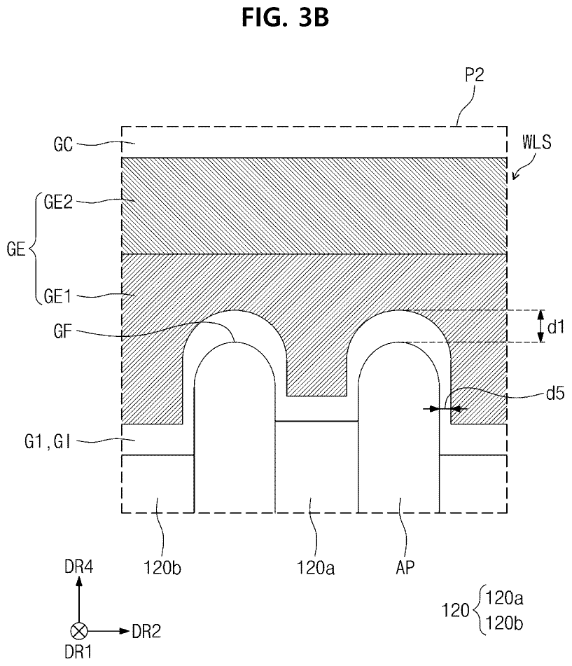

FIG. 3A is an enlarged view of portion P1 of FIG. 2B, and FIG. 3B is an enlarged view of portion P2 of FIG. 2C.

Referring to FIGS. 3A and 3B, active patterns AP and device isolation patterns 120 may be provided within the substrate 110. Impurity regions 111 and 112 (see FIG. 2A) may be formed within the active patterns AP. Bottom surfaces of the first impurity region 111 and the second impurity region 112 may be disposed at a predetermined depth from top surfaces of the active patterns AP. The first impurity regions 111 and the second impurity regions 112 may be in contact with sidewalls of a corresponding fin regions GF, among the fin regions GF. The bottom surfaces of the first impurity region 111 and the second impurity region 112 may be higher than a bottom surface of the fin region GF. The first impurity regions 111 and second impurity regions 112 may be provided as “source/drain regions” of a transistor. For example, with respect to a single active pattern AP, two buried wordline structures WLS may cross the single active pattern AP, and the drain region may be formed between the two wordline structures WLS. The source regions may be formed in regions opposite to the drain region with respect to the two wordline structures WLS. For example, the first impurity region 111 may correspond to the drain region, and the second impurity region 112 may correspond to the source region. The source region and the drain region may be formed by the first impurity regions 111 and second impurity regions 112 formed by doping or ion implantation of substantially the same type of impurities, and may be referred to interchangeably depending on the circuit configuration of a finally formed transistor.

Referring to FIG. 3A, a buried wordline structure WLS may be provided in each gate trench region GT. For example, a gate insulating pattern GI, the gate electrode GE, and the gate capping pattern GC constituting the buried wordline structure WLS may fill each of the gate trench regions GT. The gate insulating pattern GI may cover a bottom surface and a side surface of the gate trench region GT. The gate electrode GE and the gate capping pattern GC may fill the remaining portion of the gate trench region GT.

The gate electrode GE may fill a portion of the gate trench region GT. The first gate electrode GE1 may fill a lower portion of the gate trench region GT, and the second gate electrode GE2 may be provided on the first gate electrode GE1 to fill a portion of the gate trench region GT. The second gate electrode GE2 may overlap the first gate electrode GE1. A width W2 of the second gate electrode GE2 in the first direction DR1 may be smaller than a width W1 of the first gate electrode GE1. Accordingly, the volume of the first gate electrode GE1 occupying the gate trench region GT may be larger. The first gate electrode GE1 and the second gate electrode GE2 may have the same height or may have different heights.

The gate capping pattern GC may be provided on a top surface of each second gate electrode GE2.

The gate insulating pattern GI may be provided between the gate electrode GE and the device isolation pattern 120. For example, the gate insulating pattern GI may be provided between the gate electrode GE and the device isolation pattern 120.

The gate insulating pattern GI may have different thicknesses depending on a location at which the insulating pattern GI is provided on the side surface of the gate trench region GT. For example, a thickness of the gate insulating pattern GI on the bottom surface of the gate trench region GT may be the same as a thickness of a portion of the gate insulating pattern GI on the side surface of the gate trench region GT.

The gate insulating pattern GI may include a first gate insulating pattern G1 and a second gate insulating pattern G2. The first gate insulating pattern G1 may cover an inner surface of the gate trench region GT, for example, the bottom surface and the side surface of the gate trench region GT. The second gate insulating pattern G2 may cover at least a portion of the side surface of the first gate insulating pattern G1.

The first gate insulating pattern G1 may be provided between the device isolation pattern 120 and the first gate electrodes GE1 and second gate electrodes GE2. The first gate insulating pattern G1 may extend between the device isolation pattern 120 and the gate capping pattern GC.

In some implementations, the first gate insulating pattern G1 is not conformally formed on the bottom and side surfaces of the gate trench region GT and may have different thicknesses depending on a location at which the first gate insulating pattern G1 is provided. The first gate insulating pattern G1 may have different thicknesses between the portion provided on the bottom surface of the gate trench region GT and the portion provided on the side surface of the gate trench region GT. If the thickness of the first gate insulating pattern G1 provided on the bottom surface of the gate trench region GT is referred to as a first thickness d1 and the thickness of the first gate insulating pattern G1 on the side surface of the gate trench region GT is referred to as a second thickness d2, the first thickness d1 may be greater than the second thickness d2.

The second gate insulating pattern G2 is provided to compensate for the thickness of the portion in which the first gate insulating pattern G1 is formed to have a relatively small thickness, and the second gate insulating pattern G2 may also be referred to as a gate thickness compensation insulating pattern. The second gate insulating pattern G2 may be provided at a location spaced apart from the bottom surface of the gate trench region GT but adjacent to the first impurity regions 111 and second impurity regions 112, shown in FIG. 3A. For example, the second gate insulating pattern G2 may be provided between the device isolation pattern 120 and the second gate electrode GE2. The second gate insulating pattern G2 is not provided between the device isolation pattern 120 and the first gate electrode GE1. The bottom surface of the second gate insulating pattern G2 may be in contact with the top surface of the first gate electrode GE1. The second gate insulating pattern G2 may extend between the first gate insulating pattern G1 and the gate capping pattern GC. In some implementations, top surfaces of the first gate insulating pattern G1, the second gate insulating pattern G2, and the gate capping pattern GC may be coplanar.

The second gate insulating pattern G2 may have the same thickness as the first gate insulating pattern G1 provided on the side surface of the gate trench region GT. If the thickness of the second gate insulating pattern G2 is referred to as a third thickness d3, the second thickness d2 and the third thickness d3 may be substantially the same. However, the thickness of the second gate insulating pattern G2 is not limited thereto, and the third thickness d3 may be smaller than the second thickness d2. The second gate insulating pattern G2 may be configured to have a thickness that can compensate for the thickness difference based on the location of the first gate insulating pattern G1. For example, the second gate insulating pattern G2 may have a thickness corresponding to a difference d1−d2 between the first thickness d1 and the second thickness d2. As a result, the thickness of the gate insulating pattern GI provided on the side surface of the gate trench region GT may be substantially the same as the thickness of the gate insulating pattern GI provided on the bottom surface of the gate trench region GT. For example, the sum of the third thickness d3 and the second thickness d2 may be substantially the same as the first thickness. The phrase ‘the two values are substantially the same’ may mean not only that the two values are completely identical, but also that the two values are not exactly the same but fall within the margin of error due at least in part to a process tolerance.

Referring to FIG. 3B, in the fin region GF, the first gate electrode GE1, the second gate electrode GE2, and the gate capping pattern GC may be sequentially stacked on the device isolation pattern 120 and the active patterns AP.

Referring to FIG. 3A, a top surface of the first gate electrode GE1 may be at a lower level than the bottom surfaces of the first and second impurity regions 111 and 112. The second gate electrode GE2 may be formed on the first gate electrode GE1. A top surface of the second gate electrode GE2 may be at a higher level than the bottom surfaces of the first and second impurity regions 111 and 112. At least a portion of the second gate electrode GE2 may be at the same level as the first and second impurity regions 111 and 112 in the first direction.

The gate insulating pattern GI may be provided between the gate electrode GE and the active pattern AP.

Referring to FIG. 3B, the first gate insulating pattern G1 may be provided between the active pattern AP and the first gate electrode GE1 and between the device isolation pattern 120 and the first gate electrode GE1. In some implementations, the second gate insulating pattern G2 may not be provided.

The first gate insulating pattern G1 may not be conformally formed on the active patterns AP, and may have different thicknesses depending on the location of the top surface of the active pattern AP. For example, the thickness of the first gate insulating pattern G1 provided on the top surface of the active pattern AP may be different from the thickness of the first gate insulating pattern G1 provided on the side surface of the active pattern AP. The thickness of the first gate insulating pattern G1 provided on the uppermost surface of the active pattern AP may be substantially the same as the first thickness d1. If the thickness of the first gate insulating pattern G1 provided on the side surface of the active pattern AP is referred to as a fifth thickness d5, the first thickness d1 can be greater than the fifth thickness d5. The fifth thickness may be substantially the same as the second thickness.

In some implementations, the first gate insulating pattern G1 and the second gate insulating pattern G2 may either be configured separately or formed integrally in a single body. For example, an interface may or may not be present between the first gate insulating pattern G1 and the second gate insulating pattern G2. In the drawings, an interface between the first gate insulating pattern G1 and the second gate insulating pattern G2 is illustrated as a solid line for descriptive clarity. However, this is for illustration, and implementations are not limited thereto.

Referring to FIGS. 3A and 3B, the first gate insulating pattern G1 may include a silicon oxide, a silicon nitride, a silicon oxynitride, a high-κ material, or combinations thereof. The high-κ material may have a dielectric constant greater than a dielectric constant of silicon oxide. The high-κ material may include at least one metallic element. The high-κ material may include a hafnium-containing material. The hafnium-containing material may include a hafnium oxide, a hafnium silicon oxide, a hafnium silicon oxynitride, or combinations thereof. In some implementations, the high-κ material may include a lanthanum oxide, a lanthanum aluminum oxide, a zirconium oxide, a zirconium silicon oxide, a zirconium silicon oxynitride, an aluminum oxide, or combinations thereof. Other known high-κ materials may be used as the high-κ material.

The first gate insulating pattern G1 and the second gate insulating pattern G2 may include the same material or different materials. The second gate insulating pattern G2 may include a silicon oxide, a silicon nitride, a silicon oxynitride, a high-κ material, or combinations thereof.

The first gate electrode GE1 may include a low-resistance material. The first gate electrode GE1 may include metal, metal nitride, or a combination thereof. The first gate electrode GE1 may include tantalum nitride (TaN), titanium nitride (TiN), tungsten (W), tungsten nitride (WN), or combinations thereof. The first gate electrode GE1 may be formed of titanium nitride alone. In addition, the first gate electrode GE1 may be formed of a stack of titanium nitride and tungsten (TiN/W). In some implementations, the first gate electrode GE1 may include a metal silicon nitride. The metal silicon nitride may be formed by doping silicon into a metal nitride. In some implementations, the first gate electrode GE1 may include a tantalum silicon nitride (TaSiN) or a titanium silicon nitride (TiSiN). The second gate electrode GE2 and the first gate electrode GE1 may include the same material or different materials.

The first gate electrode GE1 and the second gate electrode GE2 may include materials having different work functions.

The gate capping pattern GC may serve to protect the second gate electrode GE2. The gate capping pattern GC may fill an upper portion of the gate trench region GT on the second gate electrode GE2. A top surface of the gate capping pattern GC may be disposed at the same level as the top surfaces of the first and second impurity regions 111 and 112. The gate capping pattern GC may include an insulating material. The gate capping pattern GC may include a silicon nitride, a silicon oxynitride, or a combination thereof. In some implementations, the gate capping pattern GC may include a combination of a silicon nitride and a silicon oxide. The gate capping pattern GC may include a silicon nitride liner and a spin-on dielectric SOD.

As described above, the semiconductor device according to some implementations may include a wordline structure employing a buried gate structure. The semiconductor device according to some implementations may prevent deterioration by controlling the thickness control of the gate insulating pattern.

As sizes of semiconductor devices decrease, a diameter of a gate trench region for forming a gate electrode can decrease. This can lead to reduced control of a gate insulation pattern thickness. For example, as the diameter of the gate trench area decreases, a difference in thickness between a gate insulating pattern formed on a bottom surface of the gate trench region and the gate insulating pattern formed on a side surface of the gate trench area can increase.

In some implementations, the gate insulating pattern may be formed on the bottom surface of the gate trench region to a predetermined thickness. An additional gate insulating pattern may be formed to compensate for the thickness of the gate insulating pattern formed on the side surface of the gate trench region. The sum of the thicknesses of the first gate insulating pattern G1 and the second gate insulating pattern G2 formed on the side surface of the gate trench region may be equal to the thickness of the first gate insulating pattern formed on the bottom surface of the gate trench region. Accordingly, damage to the first gate insulating pattern may be prevented and leakage current caused at least in part by gate-induced current may be reduced while maintaining the thickness of the gate insulating pattern on the side surface of the gate trench region at a sufficient thickness.

In addition, time-dependent dielectric breakdown (TDDB) caused at least in part by damage to the gate insulating layer may be reduced or prevented.

In addition, the second gate insulating pattern may be provided on the side surface of the second gate electrode and may not be provided on the side surface of the first gate electrode. In some implementations, the volume of the first gate electrode is not reduced. A sufficient volume of the first gate electrode may be secured, so that the design freedom of the gate electrode may be improved. In addition, impurities are not typically introduced to the active pattern AP at a location where the first gate electrode GE1 is provided. The likelihood of leakage current is typically negligible or low, even with a smaller thickness of the first gate insulating pattern.

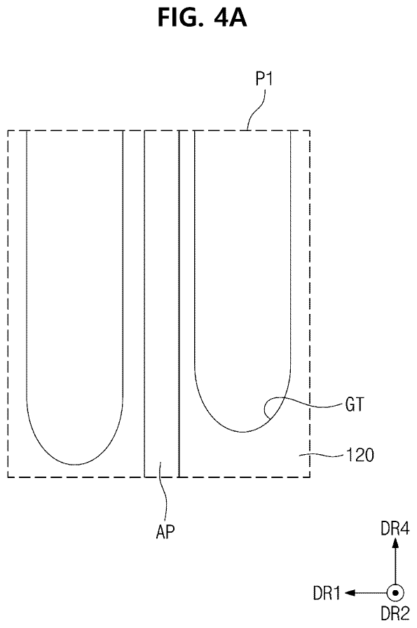

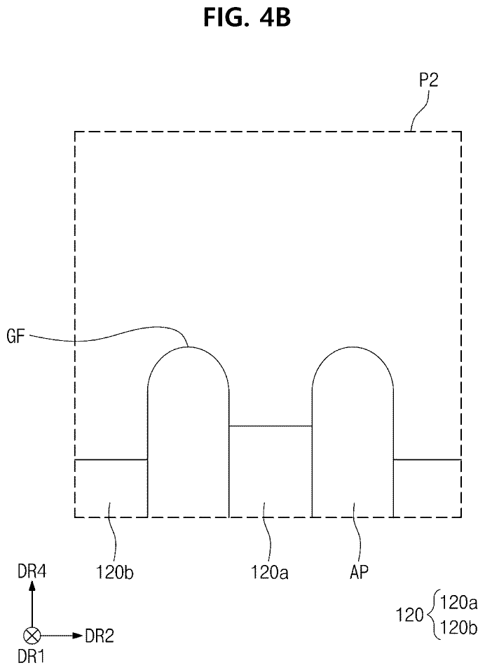

FIGS. 4A and 4B, 5A and 5B, 6A and 6B, 7A and 7B, 8A and 8B, and 9A and 9B are cross-sectional views, sequentially illustrating a method of manufacturing a buried wordline structure WLS according to some implementations. FIGS. 4A, 5A, 6A, 7A, 8A, and 9A are cross-sectional views corresponding to P1 of FIG. 2B. FIGS. 4B, 5B, 6B, 7B, 8B, and 9B are cross-sectional views corresponding to P2 of FIG. 2C.

Referring to FIGS. 4A and 4B, device isolation patterns 120 may be formed in a substrate 110, and active patterns AP may be defined by the device isolation patterns 120.

Forming the device isolation patterns 120 and the active patterns AP may include forming grooves in the substrate 110 by patterning, and filling the grooves with an insulating material to form a device isolation patterns 120. First impurity regions 111 and second impurity regions 112 may be formed in the active patterns AP.

In some implementations, the device isolation pattern 120 may include a first region 120a and a second region 120b lower than the first region 120a. When viewed in plan view, the first region 120a may correspond to a space between active patterns AP adjacent to each other in a second direction DR2, and the second region 120b may correspond to a space surrounded by four adjacent active patterns AP.

In some implementations, impurity regions may be formed by implanting impurities into the substrate 110 before the device isolation patterns 120 are formed. For example, the first impurity region 111 may be formed in a central portion of each active pattern AP, and the second impurity regions 112 may be formed at opposite ends of each active pattern AP. However, according to some implementations, the first impurity region 111 and the second impurity regions 112 may be formed after the device isolation patterns 120 is formed or in other processes.

Gate trench regions GT and fin regions GF may be formed on the device isolation patterns 120 and the active patterns AP.

The gate trench regions GT and the fin regions GF may be connected to each other, extending in the second direction DR2, and may be formed in a linear shape intersecting the active patterns AP and the device isolation patterns 120 in the second direction DR2.

The gate trench regions GT and the fin regions GF may be formed by an etching process of the substrate 110. In some implementations, the gate trench regions GT may be formed by etching the substrate 110 using a hard mask layer as an etching mask. The fin regions GF may be formed by selectively further etching the device isolation patterns 120 after the gate trench regions GT are formed.

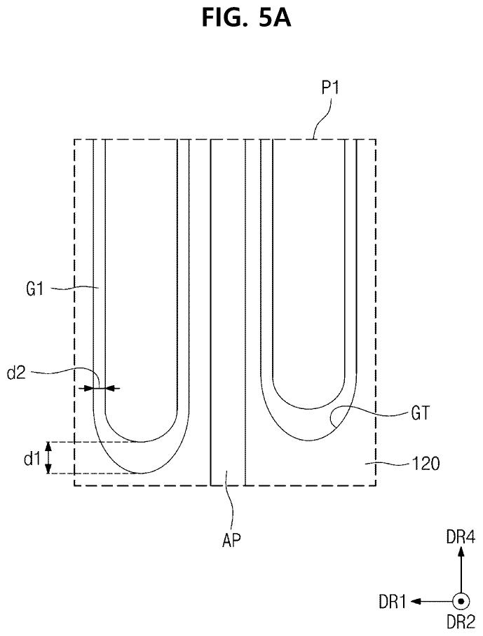

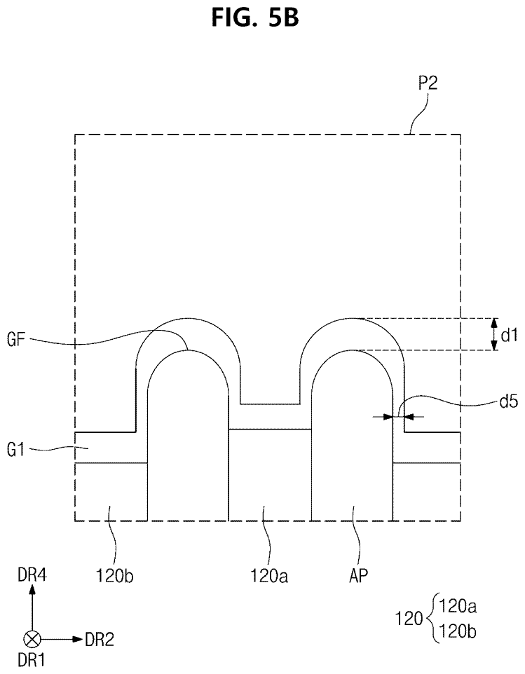

Referring to FIGS. 5A and 5B, a first gate insulating pattern G1 may be formed on top surfaces of the gate trench regions GT and the fin regions GF.

The first gate insulating pattern G1 may be formed to have different thicknesses on the bottom surface and the side surfaces of the gate trench regions GT. For example, a thickness (first thickness d1) of the first gate insulating pattern G1 provided on the bottom surface of the gate trench regions GT may be greater than a thickness (second thickness d2) of the first gate insulating pattern G1 on the side surfaces of the gate trench regions GT. The thickness (first thickness d1) of the first gate insulating pattern G1 provided on the uppermost surface of the fin regions GF may be greater than a thickness (fifth thickness d5) of the first gate insulating pattern G1 provided on the side surfaces of the active patterns AP. The fifth thickness may be substantially the same as the second thickness d2.

The first gate insulating pattern G1 may be formed by forming a first gate insulating layer in various manners ways such as chemical vapor deposition (hereinafter referred to as “CVD”), atomic layer deposition (hereinafter referred to as “ALD”), or thermal oxidation, and then patterning the first gate insulating layer. In some implementations, when the first gate insulating layer is formed by thermal oxidation, the first gate insulating pattern G1 may include a silicon oxide. In some examples, when the first gate insulating layer is formed by CVD, ALD, or the like, the first gate insulating pattern G1 may include a high-κ material, an oxide, a nitride, an oxynitride, or combinations thereof. The high-κ material may include a hafnium-containing material. The hafnium-containing material may include a hafnium oxide, a hafnium silicon oxide, a hafnium silicon oxynitride, or combinations thereof. In some implementations, the high-κ material may include a lanthanum oxide, a lanthanum aluminum oxide, a zirconium oxide, a zirconium silicon oxide, a zirconium silicon oxynitride, an aluminum oxide, or combinations thereof. Other known high-κ materials may be used as the high-κ material.

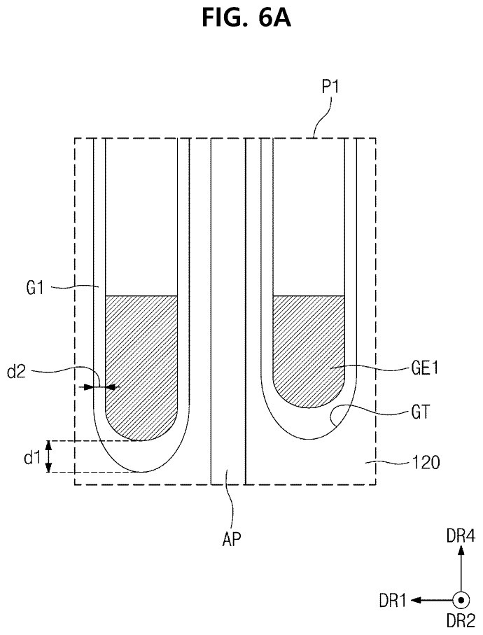

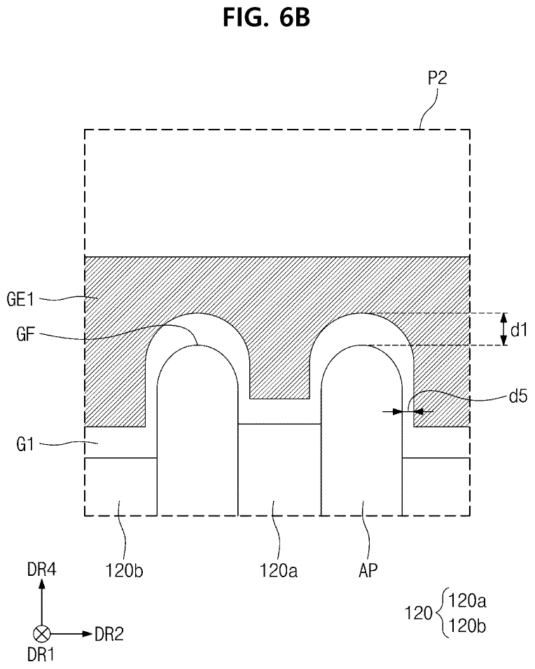

Referring to FIGS. 6A and 6B, a first gate electrode GE1 may be formed. The first gate electrode GE1 may fill a lower portion of the gate trench region GT. The first gate electrode GE1 may be formed on a top surface of the fin region GF.

The first gate electrode GE1 may be manufactured by forming a conductive layer of a conductive material on the substrate 110 and then performing a recessing process to recess the conductive layer.

The conductive material may include a metal, a metal nitride, or a combination thereof. The first gate electrode GE1 may include a tantalum nitride (TaN), a titanium nitride (TiN), tungsten (W), a tungsten nitride (WN), or combinations thereof.

The conductive layer may be formed by CVD or ALD, but implementations are not limited thereto. In some implementations, the recessing process may correspond to an etching process, such as an etch-back process using dry etching.

After the etch-back process, a portion of the side surface of the first gate insulating pattern G1 may be exposed in the gate trench region GT.

Although not illustrated, a barrier layer may be further formed on the first gate insulating pattern G1 after forming the first gate insulating pattern G1 and before forming the first gate electrode GE1. The barrier layer may include a metal-containing material. The barrier material may include a metal nitride. The barrier layer may be formed by ALD or CVD.

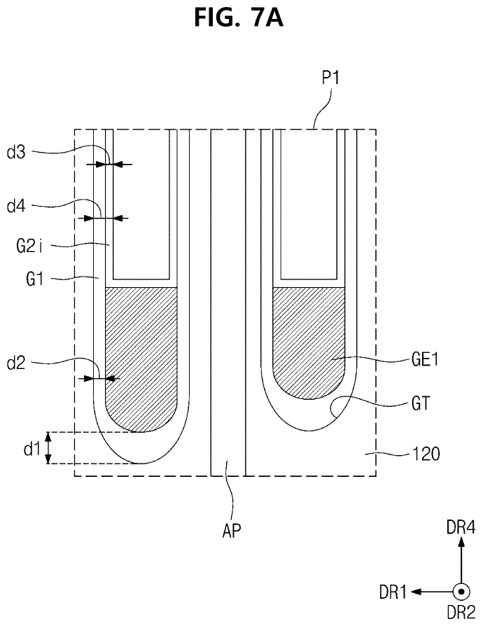

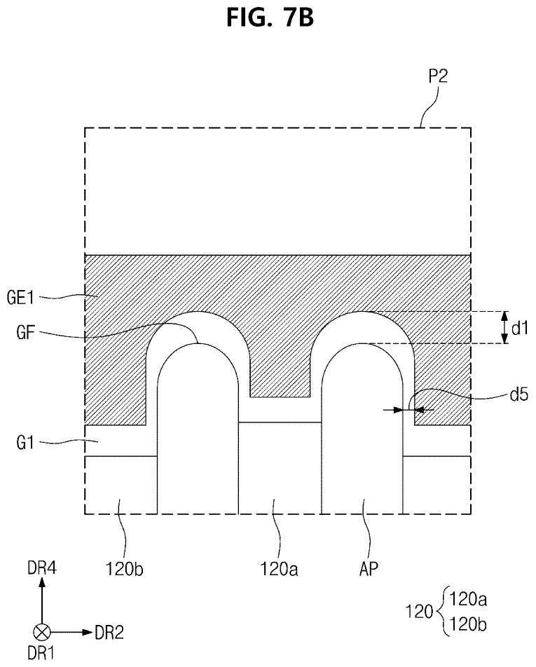

Referring to FIGS. 7A and 7B, a second gate insulating pattern G2 may be formed on a portion of the side surfaces of the first gate electrode GE1 and the first gate insulating pattern G1 in the gate trench region GT.

The second gate insulating layer may be conformally formed. The second gate insulating layer may be formed by ALD or CVD. The second gate insulating layer may include the same material as the first gate insulating pattern G1 or a different material.

In some implementations, a second gate insulating layer G2i and the first gate insulating pattern G1 may be formed to have the same thickness or different thicknesses on the side surface of the gate trench region GT. For example, the second gate insulating layer G2i may be formed to have a smaller thickness than the first gate insulating pattern G1. The second gate insulating layer G2i may be provided to compensate for a thickness of a portion in which the first gate insulating pattern G1 is formed to be a relatively small thickness, and the sum (a fourth thickness d4) of the thicknesses of the first gate insulating pattern G1 and the second gate insulating layer G2i may be equal to a thickness (a first thickness d1) of the first gate insulating pattern G1 on a lowermost surface. For example, the second gate insulating layer G2i may be provided to have a thickness corresponding to a thickness difference depending on a location of the first gate insulating pattern G1 to compensate for the thickness difference depending on the location of the first gate insulating pattern G1. For example, the second gate insulating layer G2i may have a thickness corresponding to a difference d1−d2 between the first thickness d1 and the second thickness d2.

In some implementations, the second gate insulating layer G2i may be formed by CVD, ALD, or thermal oxidation.

In some implementations, the second gate insulating layer G2i may include a silicon oxide. In some examples, when the second gate insulating layer G2i includes silicon oxide, the second gate insulating layer G2i may be formed by CVD using a silicon precursor. For example, a silicon oxidation process may be performed by providing a di-isopropylamino silane (DIPAS) seed as a silicon precursor on the substrate 110 and then providing argon (Ar) and oxygen (O₂). In some implementations, in addition to the silicon oxidation process, He/HeO treatment of the substrate 110 may be performed. In some implementations, a curing process may be performed on the second gate insulating layer G2i formed by depositing a silicon oxide to stabilize a silicon oxide layer. In some implementations, the second gate insulating layer G2i may be formed by a selective oxidation process.

However, a material of the second gate insulating layer G2i is not limited thereto, and may include a silicon nitride, a silicon oxynitride, a high-κ material, or combinations thereof.

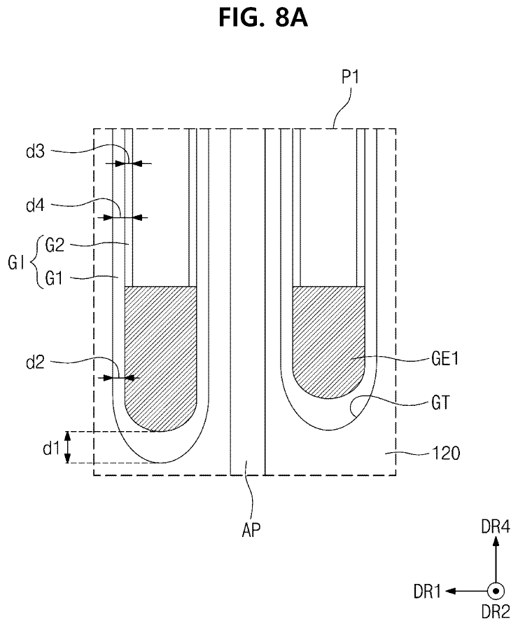

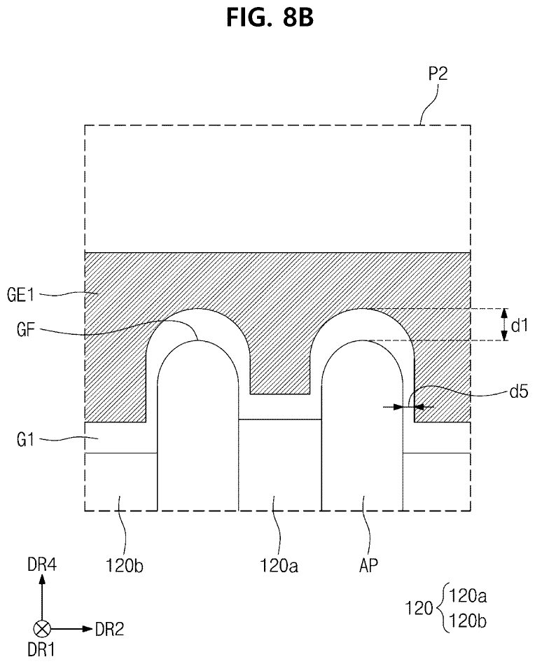

Referring to FIGS. 8A and 8B, a portion of the second gate insulating pattern G2 may be removed.

The portion of the second gate insulating pattern G2 may be removed through an etch-back process. The etch-back process allows the second gate insulating pattern G2 on the side surface of the first gate insulating pattern G1 to remain, while allowing the second gate insulating pattern G2 on the second gate electrode GE2 to be removed. Accordingly, a top surface of the first gate electrode GE1 may be exposed.

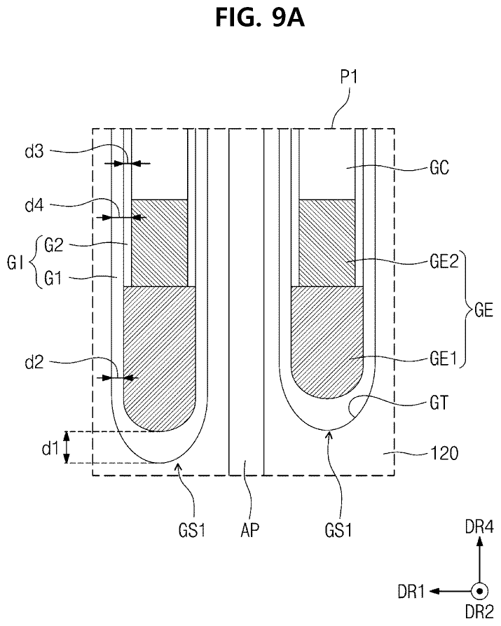

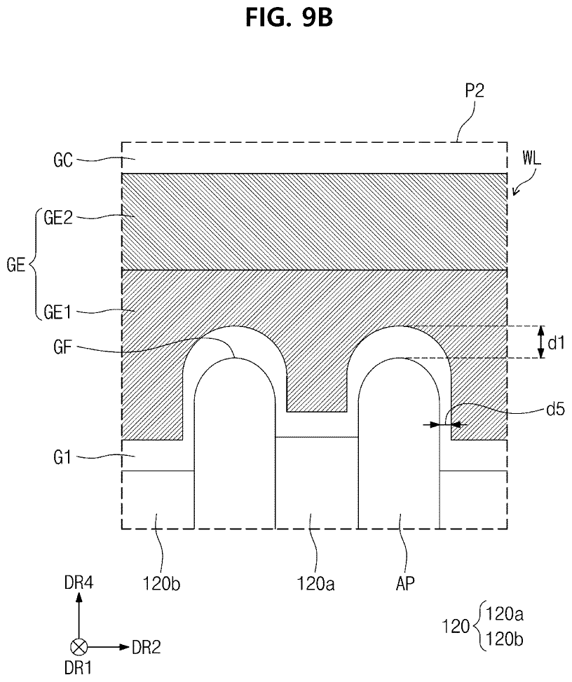

Referring to FIGS. 9A and 9B, the second gate electrode GE2 may be formed on the exposed first gate electrode GE1.

The second gate electrode GE2 may be manufactured by forming a conductive layer of a conductive material and then performing a recessing process to recess the conductive layer.

The conductive layer may be formed by CVD or ALD, but implementations are not limited thereto. The first gate electrode GE1 and the conductive layer may include different materials, or may include the same material.

The recessing process may be an etch-back process using etching. In some implementations, the etching may be dry etching. During the etch-back process, the side surface of the second gate insulating pattern G2 may be exposed and the top surface of the second gate electrode GE2 may be recessed to be lower than the top surface of the active pattern AP.

During the etch-back process of the second conductive layer, the second gate insulating pattern may be exposed while the first gate insulating pattern may not be exposed. Damage to the first gate insulating pattern G1, caused at least in part by the etch-back process of the conductive layer for the second gate electrode, may be prevented. The second gate insulating pattern G2 may serve as a protective layer to prevent etching damage of the first gate insulating pattern G1. A portion of the second gate insulating pattern G2 may be damaged during the etch-back process of the conductive layer. In some implementations, if the portion of the second gate insulating pattern G2 is damaged, the first gate insulating pattern G1 may remain without damage, so that the occurrence of leakage current may be prevented or reduced.

A gate capping pattern GC may be formed on the second gate electrode GE2. The gate capping pattern GC may include an insulating material. The gate capping pattern GC may include a silicon nitride.

Through the series of processes as described herein, a gate electrode GE including the first gate electrode GE1 and the second gate electrode GE2 may be formed.

Although not illustrated, upper structures, including a buffer layer, a bitline structure BLS, a spacer structure SPC, and a data storage pattern DSP, may be formed on the substrate 110 on which the wordline structure WLS is formed.

As set forth above, according to some implementations, a semiconductor device may have a structure designed to reduce leakage current, resulting in improved reliability thereof.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While the present disclosure has been described with reference to various examples thereof, it will be apparent to those skilled in the art that modifications and variations could be made without departing from the scope of the present disclosure as set forth in the following claims.

What is claimed is:

1. A semiconductor device comprising:
a substrate comprising a gate trench region;
a first impurity region and a second impurity region spaced apart from each other by the gate trench region;
a gate insulating pattern covering a bottom surface and a side surface of the gate trench region; and
a gate electrode disposed at a portion of the gate trench region,
wherein:
the gate insulating pattern covers the bottom surface and the side surface of the gate trench region,
the gate insulating pattern has a first thickness at a first location of the side surface of the gate trench region and a second thickness at a second location of the side surface of the gate trench region, the second thickness being different from the first thickness, and
the gate insulating pattern has a bottom thickness on the bottom surface of the gate trench region, the bottom thickness being same as a thickness of a portion of the gate insulating pattern on the side surface of the gate trench region.

2. The semiconductor device of claim 1, wherein:
the gate insulating pattern comprises:
a first gate insulating pattern covering the bottom surface and the side surface of the gate trench region; and
a second gate insulating pattern spaced apart from the bottom surface of the gate trench region and covering a portion of the side surface.

3. The semiconductor device of claim 2, wherein:
the first gate insulating pattern has a greater thickness on the bottom surface of the gate trench region than on the side surface of the gate trench region.

4. The semiconductor device of claim 3, wherein:
the bottom thickness of the first gate insulating pattern on the bottom surface of the gate trench region is equal to a sum of a thickness of the first gate insulating pattern and a thickness of the second gate insulating pattern on the side surface of the gate trench region.

5. The semiconductor device of claim 2, wherein:
the gate electrode comprises:
a first gate electrode disposed at a lower portion of the gate trench region; and
a second gate electrode on the first gate electrode; and
the second gate insulating pattern is provided between the second gate electrode and the side surface of the gate trench region.

6. The semiconductor device of claim 5, wherein:
a bottom surface of the second gate insulating pattern contacts a top surface of the first gate electrode.

7. The semiconductor device of claim 5, wherein:
the first gate electrode has a greater width than the second gate electrode.

8. The semiconductor device of claim 5, wherein:
the substrate comprises a device isolation pattern and a plurality of active patterns defined by the device isolation pattern;
the first and second impurity regions are provided in an upper portion of the plurality of active patterns; and
lower surfaces of the first and second impurity regions are at a lower level than a surface of the first gate electrode.

9. The semiconductor device of claim 2, wherein:
the substrate comprises a fin region below the gate electrode; and
the first gate insulating pattern covers a top surface and a side surface of the fin region.

10. The semiconductor device of claim 9, wherein:
the first gate insulating pattern has a thickness on the top surface of the fin region that is greater than a thickness of the first gate insulating pattern on the side surface of the fin region.

11. The semiconductor device of claim 10, wherein:
the first gate insulating pattern has a thickness on the bottom surface of the gate trench region that is a same as a thickness of the first gate insulating pattern on the top surface of the fin region, and that is greater than a thickness of the first gate insulating pattern on the side surface of the fin region.

12. The semiconductor device of claim 2, wherein:
the first gate insulating pattern and the second gate insulating pattern are formed integrally in a single body.

13. The semiconductor device of claim 5, comprising:
a gate capping pattern on the second gate electrode,
wherein the first and second gate insulating patterns are positioned between the side surface of the gate trench region and the gate capping pattern.

14. A semiconductor device comprising:
a substrate comprising an active region, wherein the active region comprises a first impurity region and a second impurity region;
a wordline structure extending in a first direction within a gate trench region on the substrate;
a bitline structure extending in a second direction on the substrate and connected to the first impurity region on a side of a gate structure, the second direction intersecting the first direction; and
a data storage pattern on the bitline structure and electrically connected to the second impurity region on a side of the wordline structure,
wherein:
the wordline structure comprises:
a gate insulating pattern covering a bottom surface and a side surface of the gate trench region; and
a gate electrode disposed at a portion of the gate trench region;
the gate insulating pattern covers the bottom surface and the side surface of the gate trench region; and
the gate insulating pattern has a first thickness at a first location of the side surface of the gate trench region and a second thickness at a second location of the side surface of the gate trench region, the second thickness being different from the first thickness, and the gate insulating pattern has a bottom thickness on the bottom surface of the gate trench region that is same as a thickness of a portion of the gate insulating pattern on the side surface of the gate trench region.

15. The semiconductor device of claim 14, wherein:
the gate insulating pattern comprises:
a first gate insulating pattern covering the bottom surface and the side surface of the gate trench region; and
a second gate insulating pattern spaced apart from the bottom surface of the gate trench region and covering a portion of the side surface.

16. The semiconductor device of claim 15, wherein:
the first gate insulating pattern has a greater thickness on the bottom surface of the gate trench region than on the side surface of the gate trench region.

17. The semiconductor device of claim 16, wherein:
the bottom thickness of the first gate insulating pattern on the bottom surface of the gate trench region is equal to a sum of a thickness of the first gate insulating pattern and a thickness of the second gate insulating pattern on the side surface of the gate trench region.

18. A method of manufacturing a semiconductor device, the method comprising:
forming a gate trench region on a substrate;
forming a first gate insulating pattern on a bottom surface and a side surface of the gate trench region, the first gate insulating pattern having a first thickness at a first location of the side surface of the gate trench region and a second thickness at a second location of the side surface of the gate trench region, the second thickness being different from the first thickness;
forming a first gate electrode in a portion of the gate trench region;
forming a second gate insulating pattern on the side surface of the gate trench region; and
forming a second gate electrode on the first gate electrode,
wherein a sum of a thickness of the first gate insulating pattern and a thickness of the second gate insulating pattern on the side surface of the gate trench region is a same as a thickness of the first gate insulating pattern on the bottom surface of the gate trench region.

19. The method of claim 18, wherein forming of the second gate insulating pattern comprises:
forming a second gate insulating layer within the gate trench region in which the first gate electrode is formed; and
patterning the second gate insulating layer on a top surface of the first gate electrode by an etch-back process.

20. The method of claim 19, wherein forming the second gate insulating layer is based on at least one of chemical vapor deposition, atomic layer deposition, or thermal oxidation.
